(19) United States
(12) Patent Application Publication
(10) Pub. No.: US 2024/0373565 A1
(43) Pub. Date: Nov. 7, 2024

(54) DISPLAY PANEL AND MOBILE TERMINAL

(71) Applicant: WUHAN CHINA STAR OPTOELECTRONICS SEMICONDUCTOR DISPLAY TECHNOLOGY CO., LTD., Hubei (CN)

(72) Inventors: Xin Liu, Wuhan, Hubei (CN); Jun Chen, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/617,298

(22) PCT Filed: Nov. 10, 2021
(86) PCT No.: PCT/CN2021/129838

§ 371 Date: Jul. 1, 2024

(30) Foreign Application Priority Data
Oct. 19, 2021 (CN) 202111214632.4

(51) Int. Cl. H05K 5/02

(52) U.S. Cl. CPC H05K 5/02

(57) ABSTRACT

A display panel and a mobile terminal are provided. The display panel includes a support layer, a display layer located on the support layer, and an optical device located on a side of the support layer away from the display layer and located in a first area. The support layer includes a first support part in a first area, a phase difference in a thickness direction of the first support part is greater than or equal to 8000 nanometers, or less than 10 nanometers.

### FIELD OF INVENTION

The present application relates to the field of display technologies, and more particularly to a display panel and a mobile terminal.

### BACKGROUND OF INVENTION

In order to realize lightness, thinness and beauty of display screens, applications of the display screens with functions such as under-screen fingerprints and under-screen camera is born by adopting a method of setting up optical devices under the screen.

Currently, polyethylene terephthalate is generally used to make a substrate to support a display layer and to avoid scratches on the display layer by an optics during an assembly process. However, the investigation found that polyethylene terephthalate has birefringence caused by optical anisotropy. This seriously affects a reliability of under-screen optical devices, and reduces an accuracy of under-screen fingerprint recognition and under-screen camera.

In summary, it is necessary to provide a display panel and a mobile terminal that can reduce a birefringence phenomenon and improve an accuracy of under-screen fingerprint recognition and under-screen camera.

### SUMMARY OF INVENTION

### Technical Problem

A purpose of the present application is to provide a display panel and a mobile terminal, which solves an existing birefringence phenomenon caused by an optical anisotropy of a substrate carrying a display layer, resulting in a technical problem of low reliability of optical devices under the screen.

### Problem Solution

### Technical Solution

An embodiment of the present application provides a display panel comprising a first area, the display panel comprises:
a support layer comprising a first support part located in the first area, wherein a phase difference in a thickness direction of the first support part is greater than or equal to 8000 nanometers, or less than 10 nanometers;
a display layer located on the support layer; and an optical device located on a side of the support layer away from the display layer;
an optical device provided in the first area;
wherein an elastic modulus of the first support part is greater than or equal to 2.5 GPa;
wherein the display panel further comprises a second area surrounding the first area, the support layer further comprises a second support part located in the second area, and an elastic modulus of the second support part is greater than the elastic modulus of the first support part.

In an embodiment, a material of the first support part comprises a super-reflex polyester film.

In an embodiment, the first support part comprises:
a first sub-support part, wherein a material of the first sub-support part comprises a super-reflex polyester film;
a second sub-support part, wherein the second sub-support part is located on the first sub-support part, and a material of the second sub-support part comprises an optical COP material.

In an embodiment, the support layer comprises:
a first support layer, wherein the first support layer and the display layer are arranged oppositely, and a material of the first support layer comprises a super-reflex polyester film;
a second support layer, wherein the second support layer is located on the first support layer, and the material of the second support layer comprises an optical COP material.

In an embodiment, a material of the first support part and a material of the second support part are the same or different.

In an embodiment, a material of the second support part comprises polyethylene terephthalate.

In an embodiment, the display panel further comprises:
a cover layer, wherein the cover layer is located on a side of the display layer away from the support layer, the cover layer comprises a first cover layer and a second cover layer located on a side of the first cover layer away from the display layer;
wherein a material of the first cover layer comprises a super-reflex polyester film, and the material of the second cover layer comprises polycarbonate.

An embodiment of the present application provides a display panel comprising a first area, the display panel comprises:
a support layer comprising a first support part located in the first area, wherein a phase difference in a thickness direction of the first support part is greater than or equal to 8000 nanometers, or less than 10 nanometers;
a display layer located on the support layer;
an optical device located on a side of the support layer away from the display layer, and the optical device provided in the first area.

In an embodiment, an elastic modulus of the first support part is greater than or equal to 2.5 GPa.

In an embodiment, a material of the first support part comprises a super-reflex polyester film.

In an embodiment, the first support part comprises:
a first sub-support part, wherein a material of the first sub-support part comprises a super-reflex polyester film;
a second sub-support part, wherein the second sub-support part is located on the first sub-support part, and a material of the second sub-support part comprises an optical COP material.

In an embodiment, the display panel further comprises a second area surrounding the first area, the support layer further comprises a second support part located in the second area, and an elastic modulus of the second support part is greater than the elastic modulus of the first support part.

In an embodiment, a material of the first support part and a material of the second support part are the same or different.

In an embodiment, a material of the second support part comprises polyethylene terephthalate.

In an embodiment, the support layer comprises:
a first support layer, wherein the first support layer and the display layer are arranged oppositely, and a material of the first support layer comprises a super-reflex polyester film;
a second support layer, wherein the second support layer is located on the first support layer, and the material of the second support layer comprises an optical COP material.

In an embodiment, the display panel further comprises:
a cover layer, wherein the cover layer is located on a side of the display layer away from the support layer, the cover layer comprises a first cover layer and a second cover layer located on a side of the first cover layer away from the display layer;
wherein a material of the first cover layer comprises a super-reflex polyester film, and the material of the second cover layer comprises polycarbonate.

In an embodiment, the display panel further comprises:
an adhesive layer, wherein the adhesive layer is located between the support layer and the display layer, the adhesive layer is used to fix the support layer and the display layer, and a material of the adhesive layer comprises a pressure-sensitive adhesive.

In an embodiment, the display panel further comprises:
a buffer layer, wherein the buffer layer is located on a side of the support layer away from the display layer, the buffer layer comprises an opening in the first area, and the optical device is located in the opening.

In an embodiment, a material of the buffer layer comprises metal, a foam, and a mesh glue.

In an embodiment, an embodiment of the present application further comprises a mobile terminal, wherein the mobile terminal comprises a terminal body and the display panel as described above, and the terminal body and the display panel are combined into one body.

### Beneficial Effect of Invention

### Beneficial Effect

The present application provides a display panel and a mobile terminal. The display panel comprises a first area; a support layer comprising a first support part located in the first area, wherein a phase difference in a thickness direction of the first support part is greater than or equal to 8000 nanometers, or less than 10 nanometers; a display layer located on the support layer; and an optical device located on a side of the support layer away from the display layer, and the optical device provided in the first area. An appropriate material selected in the present application is to set a phase difference in a thickness direction of the first support part to be greater than or equal to 8000 nanometers, or less than 10 nanometers. This makes a birefringence phenomenon of the first support part weaker or even eliminated, thereby weakening a rainbow pattern phenomenon caused thereby. This improves a reliability of under-screen optical devices, thereby improving an accuracy of under-screen fingerprint recognition and under-screen camera.

### BRIEF DESCRIPTION OF THE DRAWINGS

### Description of Drawings

The present application will be further explained with the drawings below. It should be noted that the drawings in the following description are only used to explain some embodiments of the present application. For those skilled in the art, without creative work, other drawings can be obtained from these drawings.

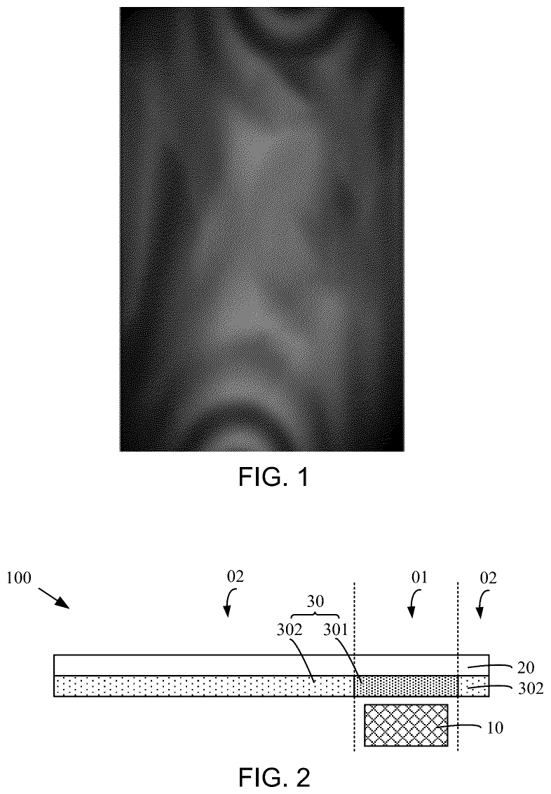

FIG. 1 is a schematic diagram of a rainbow pattern phenomenon in a display panel including a substrate made of polyethylene terephthalate material.

FIG. 2 is a cross-sectional view of a first display panel provided by an embodiment of the present application.

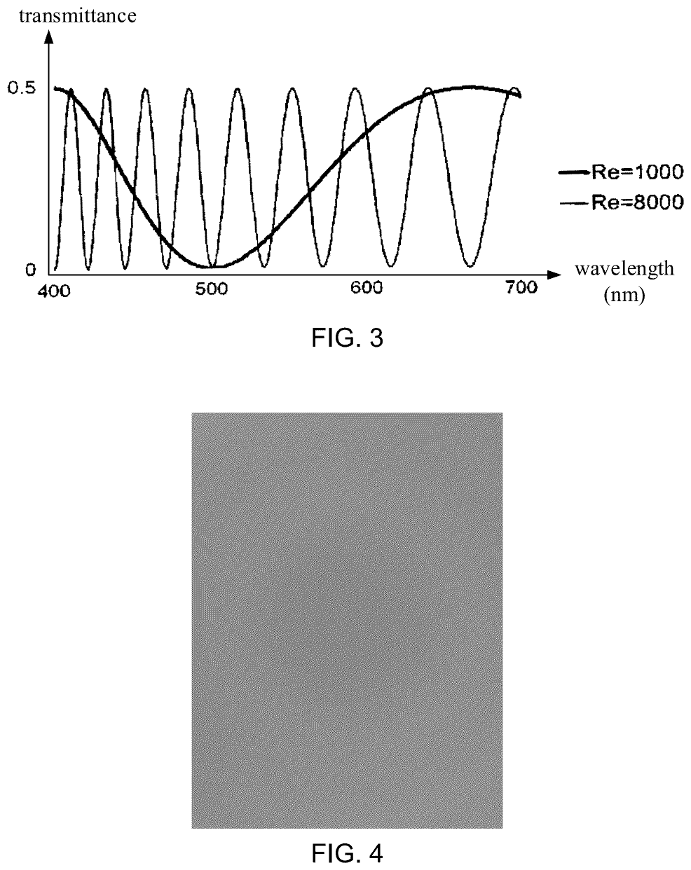

FIG. 3 is a graph of wavelength-transmittance of two materials provided in an embodiment of the present application.

FIG. 4 is a schematic diagram showing that a rainbow pattern phenomenon in a display panel provided by an embodiment of the present application is weakened.

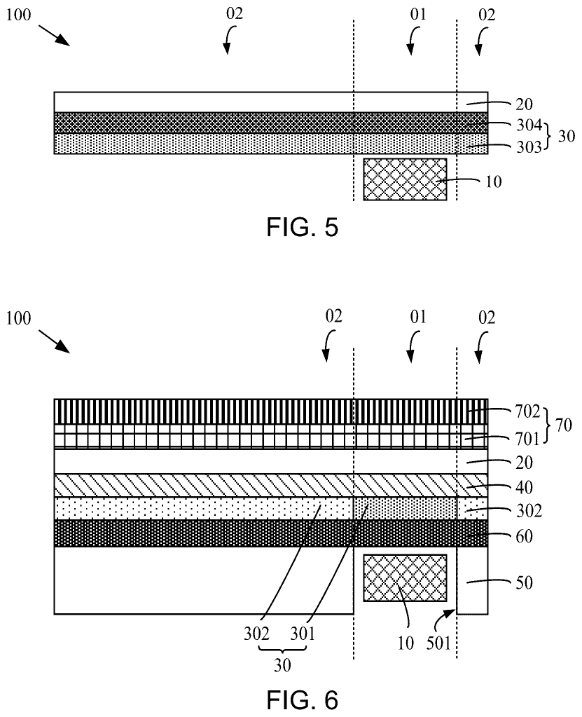

FIG. 5 is a cross-sectional view of a second display panel provided by an embodiment of the present application.

FIG. 6 is a cross-sectional view of a third display panel provided by an embodiment of the present application.

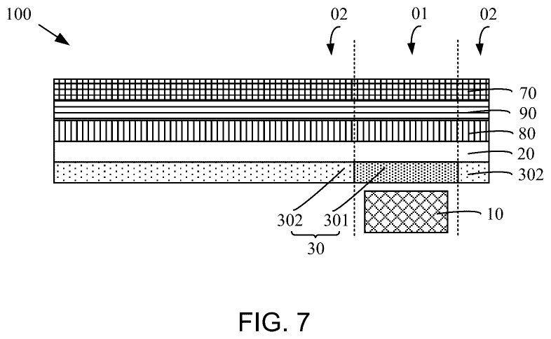

FIG. 7 is a cross-sectional view of a fourth display panel provided by an embodiment of the present application.

### EMBODIMENTS OF INVENTION

### Detailed Description of Preferred Embodiments

The technical solutions in the embodiments of the present application will be clearly and completely described below in conjunction with the drawings in the embodiments of the present application. Obviously, the described embodiments are only a part of the embodiments of the present application, rather than all the embodiments. Based on the embodiments in this application, all other embodiments obtained by those skilled in the art without creative work shall fall within the protection scope of this application.

The terms “first”, “second”, etc. in this application are used to distinguish different objects, rather than to describe a specific order. In addition, the terms “including” and “having” and any variations thereof are intended to cover non-exclusive inclusions. For example, a process, method, system, product, or device that includes a series of steps or modules is not limited to the listed steps or modules. Instead, it optionally further includes steps or modules that are not listed, or optionally further includes other steps or modules inherent to these processes, methods, products, or equipment.

The reference to “embodiments” herein means that a specific feature, structure, or characteristic described in conjunction with the embodiments may be included in at least one embodiment of the present application. The appearance of the phrase in various places in the specification does not necessarily refer to the same embodiment, nor is it an independent or alternative embodiment mutually exclusive with other embodiments. Those skilled in the art clearly and implicitly understand that the embodiments described herein can be combined with other embodiments. In addition, it should be noted that the drawings provide only structures closely related to the application. Some details that are not relevant to the application are omitted. The purpose is to simplify the drawings and make the application points clear at a glance. It does not indicate that the actual device is exactly the same as the figure, and it is not a limitation of the actual device.

For displays that use under-screen optical devices to achieve under-screen fingerprints, under-screen camera and other functions, polyethylene terephthalate is generally used to make a substrate to carry a display layer to prevent the optics from scratching the display layer during the assembly process. However, the molding process of the substrate made of polyethylene terephthalate material is biaxial stretching molding. This leads to anisotropy of the formed substrate. When light is incident, there is a birefringence effect, as shown in FIG. 1, which makes a display panel present with rainbow patterns. This seriously affects the reliability of the under-screen optical devices, and reduces the accuracy of under-screen fingerprint recognition and under-screen camera. This application proposes the following technical solutions based on the above technical problems.

The present application provides a display panel, and the display panel includes but is not limited to the following embodiments and a combination of the following embodiments.

In an embodiment, as shown in FIG. 2, a display panel 100 includes a first area 01. The display panel 100 includes a support layer 30, wherein the support layer 30 includes a first area 01 located in the first area 01; a support part 301, wherein a phase difference in a thickness direction of the first support part 301 is greater than or equal to 8000 nanometers, or less than 10 nanometers; a display layer 20, wherein the display layer 20 is located on the support layer 30; an optical device 10, wherein the optical device 10 is located on a side of the support layer 30 away from the display layer 20, and the optical device 10 is provided in the first area 01.

The optical device 10 may be arranged in contact with the first support part 301 or arranged in a non-contact manner. Further, the display panel 100 may further include a housing for accommodating the optical device 10, the support layer 30, and the display layer 20. For example, when the optical device 10 and the first support part 301 are arranged in a non-contact manner, the housing may carry the optical device 10 to fix the optical device 10 in the first area 01. Further, the support layer 30 may further include a second support part 302 connected to the first support part 301. A forming material of the second support part 302 and a forming material of the first support part 301 may be the same or different. Of course, when the two forming materials are the same, the same material can be used to form a continuous film layer as the support layer 30. It should be noted that external light can be received by the optical device 10. Further, the optical device 10 performs fingerprint recognition or image imaging according to the condition of the received light. That is, optical properties of the first support part 301 determine the condition of the light finally received by the optical device 10, which affects the reliability of the operation of the optical device 10.

On the one hand, a polymer film has optical anisotropy due to its molecular structure arrangement and external film-forming process factors. Optical heterogeneity means that the optical properties in different directions of the medium are different. When light enters different media, it is refracted into two beams. The light that obeys the law of refraction is called ordinary light. The beam of refracted light that does not obey the law of refraction is called extraordinary light. This phenomenon is called birefringence. The refractive indices of ordinary light and extraordinary light are distinguished by no and ne respectively. Optical birefringence Δn is defined as the refractive index difference between extraordinary light and ordinary light, that is, Δn=ne−no. The birefringent polymer film will cause phase difference (retardation) when letting light pass, which will affect the path and characteristics of light. It can be understood that the birefringence characteristic of the first support part 301 made of a material with a phase difference in the thickness direction of less than 10 nanometers in this embodiment is relatively weak. That is, the rainbow pattern of the display panel can be weakened, and the impact on the accuracy of under-screen fingerprint recognition and under-screen camera can be weakened.

On the other hand, as shown in FIG. 3, for a material having a retardation Re in the thickness direction of 1000, the transmittance of visible light in a continuous section with a wavelength of about 500 nanometers is low. Since this interval is continuous, the probability that light cannot pass through is greatly increased. Correspondingly, the probability that the light is reflected to show the rainbow pattern phenomenon is also greatly increased. It can be understood that for the first support part 301 made of a material with a phase difference Re in the thickness direction of 8000 nanometers in this embodiment, as the wavelength of visible light increases, the transmittance of light is alternately larger and smaller. In addition, the wavelength range corresponding to each larger or smaller transmittance is smaller, and there is no phenomenon that the transmittance of visible light in a large continuous interval is low. Instead, the wavelength range corresponding to each larger transmittance is distributed over the entire range of visible light wavelengths. This avoids the low transmittance of visible light in a large continuous section. In combination with the above discussion, in this embodiment, the first support part 301 made of a material with a phase difference Re in the thickness direction of 8000 nanometers greatly reduces the probability that light cannot pass through in the visible light range. Correspondingly, the probability that the light is reflected to show the rainbow pattern phenomenon is reduced, and the impact on the accuracy of under-screen fingerprint recognition and under-screen camera is weakened.

In summary, in this embodiment, a film layer with a phase difference in the thickness direction greater than or equal to 8000 nanometers or less than 10 nanometers is used as the first support part 301. When light enters the display panel 100, as shown in FIG. 4, the rainbow pattern phenomenon of the display panel 100 is obviously weakened, which weakens the influence on the accuracy of under-screen fingerprint recognition and under-screen camera.

In an embodiment, the clastic modulus of the first support part 301 is greater than or equal to 2.5 GPa. It should be noted that although the first support part 301 can be made of optical COP material, triacetate film, acrylic and other materials with a retardation of less than 10 nanometers in the thickness direction. However, the elastic modulus of optical COP materials, triacetate cellulose film, and acrylic is small, which results in the film layer being brittle and poor in stiffness. It is understandable that in this embodiment, when the phase difference in the thickness direction is greater than or equal to 8000 nanometers, or less than 10 nanometers, appropriate materials or processes are further selected to produce the first support portion 301 with an elastic modulus greater than or equal to 2.5 GPa. This can make the first support part 301 alleviate the rainbow pattern phenomenon while taking into account the hardness of the first support part 301. This has sufficient stiffness to support the display layer 20 and reduce the risk of the display layer 20 falling or loosening.

In an embodiment, the material for forming the first support portion 301 includes a super-reflex polyester film. The super-reflex polyester film can be obtained by changing the structural composition, material ratio and manufacturing process of the polyester plastic material. Specifically, the first support part 301 made of the super-reflex polyester film in this embodiment can meet the following requirements: the phase difference in the thickness direction is greater than or equal to 8000 nanometers, and the clastic modulus is greater than or equal to 2.5 GPa. It is understandable that the use of super-reflex polyester film to make the first support part 301 can relieve the rainbow pattern phenomenon while taking into account the hardness of the first support part 301. This has sufficient stiffness to support the display layer 20 and reduce the risk of the display layer 20 falling or loosening.

Further, the first support part 301 made of super-reflex polyester film can also meet the following requirements: the transmittance is greater than or equal to 92%, the haze is not greater than 1%, and the glass transition temperature is 90° C. It should be noted that the substrate made of polyethylene terephthalate meets the following requirements: the phase difference in the thickness direction is not greater than (−6000) nanometers, the transmittance is greater than or equal to 92%, and the haze is not greater than 1%, the glass transition temperature is 90° C. It is understandable that the first support part 301 made of super-reflex polyester film is compared with a substrate made of polyethylene terephthalate, except that it has a larger phase difference in thickness direction to alleviate rainbow pattern phenomenon, it also has higher transmittance and smaller haze. This can reduce the impact on external light, has higher authenticity, and has a higher glass transition temperature. That is, the characteristics need to change sharply near a higher temperature. This improves the stability of the characteristics. In summary, the first support part 301 made of super-reflex polyester film can further improve the reliability of the operation of the optical device 10, so as to improve the accuracy of under-screen fingerprint recognition and under-screen camera.

In one embodiment, as shown in FIG. 2, the first support part 301 includes: a first sub-support part, wherein a constituent material of the first sub-support part includes a super-reflex polyester film; a second sub-support portion, wherein the second sub-support part is located on the first sub-support part, and a constituent material of the second sub-support part includes an optical COP material. According to the above analysis, the second sub-support part made of optical COP material can solve the problem of rainbow pattern. At the same time, although it is relatively brittle and has poor stiffness, the first sub-support part made of super-reflex polyester film has greater stiffness to support the second sub-support. This can still make the first support part 301 take into account the stiffness and solve the problem of rainbow patterns.

In an embodiment, as shown in FIG. 2, the display panel 100 further includes a second area 02 surrounding the first area 01. The second support part 302 may be located in the second area 02. The clastic modulus of the second support part 302 is greater than the elastic modulus of the first support part 301. According to the above discussion, the first support part 301 located in the first area 01 needs to alleviate the rainbow pattern phenomenon. That is, it suffices that the phase difference in the thickness direction of the first support part 301 is greater than or equal to 8000 nanometers, or less than 10 nanometers. It should be noted that the area of the first area 01 is much smaller than the area of the second area 02. That is, the area occupied by the first support part 301 in the support layer 30 is relatively small. That is, the hardness of the first support part 301 has a small influence on the overall hardness of the support layer 30, and also has a small influence on supporting the display layer 20.

It can be understood that, in this embodiment, it is considered that the second support part 302 occupies a relatively large area in the support layer 30. Setting the clastic modulus of the second support part 302 to be greater than the elastic modulus of the first support part 301 can make the overall hardness of the support layer 30 larger, so as to better support the display layer 20, and reduce the risk of the display layer 20 falling or loosening.

In an embodiment, as shown in FIG. 2, the forming material of the first support part 301 and the forming material of the second support part 302 are the same or different. Specifically, when the forming material of the first support part 301 and the forming material of the second support part 302 are the same, the first support part 301 and the second support part 302 can be formed by using, but not limited to, a super-reflex polyester film integrally formed to form the support layer 30. Specifically, when the forming material of the first support part 301 and the forming material of the second support part 302 are different, the first support part 301 and the second support part 302 may be manufactured separately in one side of the display layer 20. It is also possible to fix the first support part 301 and the second support part 302 connected to one side of the display layer 20.

In one embodiment, as shown in FIG. 2, the forming material of the second support part 302 includes polyethylene terephthalate. In combination with the above discussion, when the forming material of the first support part 301 and the forming material of the second support part 302 are different, a viscous substance may be provided in at least one of the outer side of the first support part 301 prepared in advance and the inner side of the second support part 302 prepared in advance to connect the two together. Alternatively, the material for forming the second support part 302 may be used to form a whole layer of the second support film above the corresponding film layer, and then the second support film may be dug to form the second support part 302. Then place the material for forming the first support part 301 in the hole of the second support part 302, and form the first support part 301 filled inside the second support part 302 through a related manufacturing process.

In an embodiment, as shown in FIG. 5, the support layer 30 includes: a first support layer 303, wherein the first support layer 303 and the display layer 20 are disposed oppositely, and the composition material of the first support layer 303 includes a super-refractive polyester film; a second support layer 304, wherein the second support layer 304 is located on the first support layer 303, and the composition material of the second support layer 304 includes an optical COP material. In the same way, the second support layer 304 made of optical COP material can solve the problem of rainbow patterns. At the same time, although it is relatively brittle and has poor stiffness, the first support layer 303 made of super-reflex polyester film has greater stiffness to support the second support layer 304. This can still enable the support layer 30 to take into account the stiffness and solve the problem of rainbow patterns. It can be understood that the first support layer 303 and the second support layer 304 in this embodiment are arranged in a whole layer, which can avoid the arrangement in regions and improve the production efficiency of the support layer 30. It should be noted that there is no limitation on the forming material of the second support layer 304 here. In combination with the above discussion, it can be seen that the forming material of the second support layer 304 can also be, but not limited to, triacetate cellulose film or acrylic.

In an embodiment, as shown in FIG. 6, the display panel 100 further includes: an adhesive layer 40, wherein the adhesive layer 40 is located between the support layer 30 and the display layer 20, the adhesive layer 40 is used to fix the support layer 30 and the display layer 20, and the adhesive layer 40 is formed of a pressure-sensitive adhesive. The pressure-sensitive adhesive is a type of adhesive that is sensitive to pressure. When pressure is applied, it achieves the purpose of bonding any adherend to a smooth surface. The pressure-sensitive adhesive is a type of adhesive that is sensitive to pressure. When pressure is applied, it achieves the purpose of bonding any adherend to a smooth surface. Furthermore, if the adhesive surface of the adherend is damaged, the pressure-sensitive adhesive does not contaminate the surface of the adherend. In addition to the main components, pressure-sensitive adhesives also include auxiliary components, such as tackifying resins, plasticizers, fillers, viscosity modifiers, vulcanizing agents, antioxidants, solvents, etc. It is understandable that neither the support layer 30 nor the display layer 20 has adhesiveness. In this embodiment, the two can be fixed by setting the pressure-sensitive adhesive. And it can alleviate the impact of external force on the display layer 20 when the display panel 100 is assembled.

In one embodiment, as shown in FIG. 6, the display panel 100 further includes: a buffer layer 50, wherein the buffer layer 50 is located on the side of the support layer 30 away from the display layer 20, the buffer layer 50 includes an opening 501 located in the first region 01, and the optical device 10 is located in the opening 501. Specifically, the buffer layer 50 may be located in the second area 02. That is, the buffer layer 50 may be disposed around the optical device 10. This prevents the light irradiated around the optical device 10 from being received by the optical device 10. And this prevents external impurities from falling on the optical device 10 during operation. In summary, the reliability of the operation of the optical device 10 can be ensured. Further, the thickness of the buffer layer 50 may be greater than or equal to the thickness of the optical device 10. This prevents the housing of the display panel 100 from scratching the bottom of the optical device 10.

Specifically, when the optical device 10 is carried on the housing of the display layer 20, that is, the optical device 10 and the support layer 30 are arranged in a non-contact manner, a whole layer of buffer film can be formed on the side of the support layer 30 away from the display layer 20 first. Then, the buffer layer 50 having the opening 501 corresponding to the first area 01 is formed by etching. Alternatively, the buffer layer 50 with the opening 501 may be pasted on the side of the support layer 30 away from the display layer 20.

In one embodiment, the constituent materials of the buffer layer 50 include metal, foam and mesh glue. Specifically, the buffer layer 50 may include a metal layer, a graphite layer on the metal layer, a flexible layer on the graphite layer, a foam layer on the flexible layer, and a grid glue layer on the foam layer. The constituent material of the metal layer may include, but is not limited to, copper. The constituent material of the graphite layer may be graphite. The constituent material of the flexible layer may include, but is not limited to, polyimide. The constituent material of the foam layer may be foam. The grid adhesive layer can be made of glass woven grid cloth as a base material and compounded by coating a dry glue emulsion. It can be understood that the metal layer can enhance the hardness of the buffer layer 50, heat dissipation and shield electromagnetic fields. The graphite layer can homogenize the heat of the buffer layer 50 to avoid heat concentration. The flexible layer can improve the mechanical properties of the buffer layer 50. The foam layer has a buffering effect. The mesh adhesive layer can shield light, attach the buffer layer 50 and other film layers, and vent gas.

In one embodiment, as shown in FIG. 6, the display panel 100 further includes a reinforcement layer 60, the reinforcement layer 60 is located on the side of the buffer layer 50 close to the display layer 20, and a forming material of the reinforcement layer 60 includes stainless steel. It should be noted that when the first support part 301 and the second support part 302 are formed of different materials, since the buffer layer 50 is located in the second area 02, the first support part 301 is close to one side of the optical device 10 is in an unsupported state. When the first support part 301 and the adhesive layer 40 are incompletely attached or the connection between the first support part 301 and the second support part 302 is loosened, the first support part 301 is very easy to lift up or even fall off.

It is understandable that in this embodiment, by providing the reinforcement layer 60 between the buffer layer 50 and the support layer 30, it can be used to carry the support layer 30 to reduce the pressure applied to the support layer 30. This reduces the probability that the first support part 301 is easily tilted or even falls off. Further, the hardness of the reinforcement layer 60 made of stainless steel is greater than the hardness of the support layer 30 and the hardness of the buffer layer 50. This can better fix the shape of the support layer 30 and the buffer layer 50, and further improves the support effect for the display layer 20.

In one embodiment, as shown in FIG. 6, the display panel 100 further includes: a cover layer 70, wherein the cover layer 70 is located on the side of the display layer 20 away from the support layer 30, the cover layer 70 includes a first cover plate layer 701 and a second cover plate layer 702 located on a side of the first cover plate layer 701 away from the display layer 20. The forming material of the first cover layer 701 includes a super-reflex polyester film, and the forming material of the second cover layer 702 includes polycarbonate.

Polycarbonate is a linear molecule. That is, the second cover layer 702 made of polycarbonate has extremely low optical anisotropy and low phase difference, which can reduce light interference and polarization. The super-refractive polyester film has a high phase difference and can prevent rainbow patterns. It is understandable that in the cover layer 70 in this embodiment, the first cover layer 701 made of super-folding polyester film and the second cover layer 702 made of polycarbonate are laminated. This can combine the advantages of the two to further improve the reliability of the operation of the display panel 100.

Furthermore, as shown in FIG. 7, the display panel 100 may further include a polarizing layer 80 on the display layer 20 and an optical glue layer 90 between the polarizing layer 80 and the cover layer 70. The optical adhesive layer 90 is used to fix the cover layer 70 on the optical adhesive layer 90. The display layer 20 may include a circuit layer and a light emitting layer on the circuit layer. The light emitting layer and the circuit layer are electrically connected to obtain corresponding electrical signals. Further, a touch layer may be provided on the display layer 20 to realize a touch function. The specific position of the touch layer is not limited here.

The present application provides a mobile terminal. The mobile terminal includes a terminal body and a display panel as described above, and the terminal body and the display panel are combined into one body.

The present application provides a display panel and a mobile terminal. The display panel comprises a first area; a support layer comprising a first support part located in the first area, wherein a phase difference in a thickness direction of the first support part is greater than or equal to 8000 nanometers, or less than 10 nanometers; a display layer located on the support layer; and an optical device located on a side of the support layer away from the display layer, and the optical device provided in the first area. An appropriate material selected in the present application is to set a phase difference in a thickness direction of the first support part to be greater than or equal to 8000 nanometers, or less than 10 nanometers. This makes a birefringence phenomenon of the first support part weaker or even eliminated, thereby weakening a rainbow pattern phenomenon caused thereby. This improves a reliability of under-screen optical devices, thereby improving an accuracy of under-screen fingerprint recognition and under-screen camera.

The display panel and the mobile terminal provided by the embodiments of the present application are described in detail above. Specific examples are used in this article to illustrate the principle and implementation of this application. The descriptions of the above embodiments are only used to help understand the technical solutions and core ideas of the present application. Those of ordinary skill in the art should understand that they can still modify the technical solutions described in the foregoing embodiments, or equivalently replace some of the technical features. However, these modifications or replacements do not cause the essence of the corresponding technical solutions to deviate from the scope of the technical solutions of the embodiments of the present application.

What is claimed is:

1. A display panel, comprising:
a first area;
a support layer comprising a first support part located in the first area, wherein a phase difference in a thickness direction of the first support part is greater than or equal to 8000 nanometers, or less than 10 nanometers;
a display layer located on the support layer; and
an optical device located on a side of the support layer away from the display layer, and the optical device provided in the first area;
wherein an elastic modulus of the first support part is greater than or equal to 2.5 GPa;
wherein the display panel further comprises a second area surrounding the first area, the support layer further comprises a second support part located in the second area, and an elastic modulus of the second support part is greater than the elastic modulus of the first support part.

2. The display panel according to claim 1, wherein a material of the first support part comprises a super-reflex polyester film.

3. The display panel according to claim 2, wherein the first support part comprises:
a first sub-support part, wherein a material of the first sub-support part comprises a super-reflex polyester film; and
a second sub-support part, wherein the second sub-support part is located on the first sub-support part, and a material of the second sub-support part comprises an optical COP material.

4. The display panel according to claim 2, wherein the support layer comprises:
a first support layer, wherein the first support layer and the display layer are arranged oppositely, and a material of the first support layer comprises a super-reflex polyester film; and
a second support layer, wherein the second support layer is located on the first support layer, and the material of the second support layer comprises an optical COP material.

5. The display panel according to claim 1, wherein a material of the first support part and a material of the second support part are the same or different.

6. The display panel according to claim 1, wherein a material of the second support part comprises polyethylene terephthalate.

7. The display panel according to claim 1, further comprising:
a cover layer, wherein the cover layer is located on a side of the display layer away from the support layer, the cover layer comprises a first cover layer and a second cover layer located on a side of the first cover layer away from the display layer;
wherein a material of the first cover layer comprises a super-reflex polyester film, and the material of the second cover layer comprises polycarbonate.

8. A display panel, comprising:
a first area;
a support layer comprising a first support part located in the first area, wherein a phase difference in a thickness direction of the first support part is greater than or equal to 8000 nanometers, or less than 10 nanometers;
a display layer located on the support layer; and
an optical device located on a side of the support layer away from the display layer, and the optical device provided in the first area.

9. The display panel according to claim 8, wherein an elastic modulus of the first support part is greater than or equal to 2.5 GPa.

10. The display panel according to claim 9, wherein a material of the first support part comprises a super-reflex polyester film.

11. The display panel according to claim 10, wherein the first support part comprises:
a first sub-support part, wherein a material of the first sub-support part comprises a super-reflex polyester film; and
a second sub-support part, wherein the second sub-support part is located on the first sub-support part, and a material of the second sub-support part comprises an optical COP material.

12. The display panel according to claim 8, wherein the display panel further comprises a second area surrounding the first area, the support layer further comprises a second support part located in the second area, and an elastic modulus of the second support part is greater than the elastic modulus of the first support part.

13. The display panel according to claim 12, wherein a material of the first support part and a material of the second support part are the same or different.

14. The display panel according to claim 12, wherein a material of the second support part comprises polyethylene terephthalate.

15. The display panel according to claim 10, wherein the support layer comprises:
a first support layer, wherein the first support layer and the display layer are arranged oppositely, and a material of the first support layer comprises a super-reflex polyester film; and
a second support layer, wherein the second support layer is located on the first support layer, and the material of the second support layer comprises an optical COP material.

16. The display panel according to claim 8, further comprising:
a cover layer, wherein the cover layer is located on a side of the display layer away from the support layer, the cover layer comprises a first cover layer and a second cover layer located on a side of the first cover layer away from the display layer;
wherein a material of the first cover layer comprises a super-reflex polyester film, and the material of the second cover layer comprises polycarbonate.

17. The display panel according to claim 8, further comprising:
an adhesive layer, wherein the adhesive layer is located between the support layer and the display layer, the adhesive layer is used to fix the support layer and the display layer, and a material of the adhesive layer comprises a pressure-sensitive adhesive.

18. The display panel according to claim 8, further comprising:
a buffer layer, wherein the buffer layer is located on a side of the support layer away from the display layer, the buffer layer comprises an opening in the first area, and the optical device is located in the opening.

19. The display panel according to claim 18, wherein a material of the buffer layer comprises metal, a foam, and a mesh glue.

20. A mobile terminal, wherein the mobile terminal comprises a terminal body and the display panel according to claim 8, and the terminal body and the display panel are combined into one body.
